(19) United States
(12) Patent Application Publication
(10) Pub. No.: US 2011/0001717 A1
(43) Pub. Date: Jan. 6, 2011

(54) Narrow Border for Capacitive Touch Panels

(76) Inventors: Charles Hayes, Northfield, MN (US); Galen Murray, Northfield, MN (US); Brian Cohn, Northfield, MN (US)

Correspondence Address: MARSH, FISCHMANN & BREYFOGLE LLP, 8055 East Tufts Avenue, Suite 450, Denver, CO, 80237, US

(21) Appl. No.: 12/830,573

(22) Filed: Jul. 6, 2010

Related U.S. Application Data
(60) Provisional application No. 61/223,259, filed on Jul. 6, 2009.

(51) Int. Cl. G06F 3/041; H05K 3/00

(52) U.S. Cl. 345/173; 427/97.4

(57) ABSTRACT

A touch screen sensor assembly and associated method for manufacturing the touch screen sensor assembly are provided. The touch screen assembly includes one or more transparent substrates that are arranged above a display. Each of the transparent substrates may include a conductive layer that is disposed adjacent to a surface of a corresponding one of the substrates. In addition, a set of conductive traces may be disposed on each of the transparent substrates and in conductive communication with the corresponding conductive layer. At least one of the sets of conductive traces may be deposited using electro deposition or vacuum deposition techniques so as to reduce a width of each trace, thereby reducing the size of a non-transparent border that surrounds the transparent substrates, maximizing the available portion of the transparent substrates for use in touch sensing.

### CROSS-REFERENCE TO RELATED APPLICATION

This application claims priority under 35 U.S.C. 119 to U.S. Provisional Application No. 61/223,259, entitled: “NARROW BORDER FOR CAPACITIVE TOUCH PANELS,” filed on Jul. 6, 2009, the contents of which are incorporated herein as if set forth in full.

### BACKGROUND

Many devices use touch screens or panels as a convenient and intuitive way for users to both view and enter information. Common applications include mobile phones, PDAs, ATMs, GPS navigation systems, electronic games, and computer interfaces, to name just a few examples. Touch screens allow a user to interact with the device by using a finger or stylus to touch objects displayed on a screen, such as icons, text, buttons, etc. In some applications, a user may also “write” and/or “draw” directly on a touch screen, such as in a PDA or other device that implements character recognition.

There are numerous technologies used to implement touch screens, including technologies that use the electrical property of capacitance to detect user inputs. A capacitive touch screen sensor is one type of sensor that generally operates by capacitive coupling through a transparent dielectric layer to a user's finger (or a stylus). This type of sensor typically includes a passive sensing circuit with multiple transparent electrodes, each producing an electric field across the touch sensitive area of the sensor. The capacitive sensing circuit may be adjacent to a transparent sensor substrate (e.g., glass or polymer). Other applications for capacitive touch sensors include non-transparent touch panels (e.g., laptop mouse pads). In these applications, the capacitive sensing circuit may be positioned adjacent to a non-transparent sensor substrate (e.g., an opaque polymer).

A touch near one or more electrodes of the sensing circuit may affect the electric field and create a signal that can be detected. A set of electrical connections are made between the sensing circuit and the detection electronics (e.g., a controller) that resolves the signals to determine the location of the touch on the sensor. The coordinates to the location may then be communicated to another processor such as a host computer for further processing.

Touch sensors utilizing one or more patterned sensing layers are often used to determine the coordinates of a touch with high accuracy, provided that the sensing layers have suitable pattern geometry. One example of a touch sensor is a touch screen assembly 10 that includes two patterned conductive coatings or layers 12, 14, as shown in FIG. 1A and FIG. 1B. The patterned conductive coatings 12, 14 may be made from a transparent conductive material, such as indium tin oxide (ITO), and each layer is generally disposed on an insulating substrate (not shown). In this example, each row of conducting elements of each of the sensor layers 12, 14 includes a series of diamond-shaped electrodes that are connected to each other with short strips of relatively narrow rectangles. A dielectric layer 16 separates the two conductive layers 12, 14, and serves to prevent them from coming into direct contact with each other. As an example, the dielectric layer 16 may include an adhesive manufactured from any non-conductive, transparent material.

As shown, the end of each row of the two patterned conductive layers 12, 14 is coupled to one of a set of lead lines 15 that are in turn coupled to a controller 20. The controller 20 may include circuitry for providing excitation currents to the capacitive sensors 12, 14 and for detecting signals generated by the sensors. Further, the controller 20 may include logic for processing the signals and conveying touch information to another part of an electronic device, such as a processor.

The lead lines 15 that connect the transparent conductive layers 12, 14 to the controller 20 may be conductive traces that are screen printed onto the transparent substrate such that they contact the transparent conductive oxide in order to establish an electrical connection between the transparent conductive layers 12,14 and the detection electronics on the controller 20. For example, the traces 15 may be screen printed with an organic paste loaded with silver particles. The traces 18 may have a minimum width of 200 μm with spacing between traces of 200 μm. In this regard, a pitch of the traces, comprising a trace and a space between the next trace, may be 400 μm in width. When considering that numerous pitches are usually provided, the conductive traces 15 occupy a relatively large space on the transparent substrate. This results in border areas 17, 18 surrounding the panel. While the borders 17,18 surrounding the transparent conductive layers function as areas sensitive to touch, the conductive traces 18 are not transparent, and thus in many touch sensor applications (e.g. touch screens) the borders 17, 18 cannot be placed over the display and do not function as part of an active area of the touch sensor. As a result, a non-touch border 23 surrounds the touch sensitive panel, limiting the available portion of the transparent substrate to be used as a touch sensor and requiring that the sensor include a border to accommodate the conductive traces.

The relatively large border 23 may be undesirable for a variety of reasons. As stated above, touch screens may be used in portable or mobile devices such as mobile phones or PDAs. In such applications, it may be desirable to reduce the overall size of the device while maximizing the size of the display and the area used for touch inputs. Accordingly, a large border 23 surrounding the transparent conductive layers 12, 14 detracts from the portion of the transparent substrate that can be used as a touch sensitive input area. Moreover, touch screens used in alternative applications other than mobile devices may also take advantage of a narrow border area in order to meet requirements for display designs, relating either to functionality or the aesthetic quality of the display.

### SUMMARY

Disclosed herein is a capacitive touch screen panel. The touch screen panel includes a first transparent substrate that includes a first conductive layer disposed adjacent to a surface thereof; a second transparent substrate that includes a second conductive layer disposed adjacent to a surface thereof; a first set of conductive traces disposed on the first transparent substrate and in conductive communication with the first conductive layer; and a second set of conductive traces disposed on the second transparent substrate and in conductive communication with the second conductive layer, wherein at least one of the first set of conductive traces and the second set of conductive traces are deposited by one of electro deposition and vacuum deposition.

A space may separate each of the conductive traces. In addition, each of the conductive traces may have a trace width that is less than 80 μm, and each of the spaces may have a space width that is less than 80 μm.

The capacitive touch screen panel may further comprise a third transparent substrate that includes a third conductive layer disposed adjacent to a surface thereof and a third set of conductive traces disposed on the third transparent substrate and in conductive communication with the third conductive layer, where the third set of conductive traces may be deposited by electro deposition, vacuum deposition, or screen printing. The first transparent substrate, the first conductive layer, and the first set of conductive traces may form a top layer, where a transparent cover layer may be associated with the top layer. The first set of conductive traces may electrically connect with a top surface of the first conductive layer, and the first set of conductive traces may electrically connect with a bottom surface of the first conductive layer.

One of the first and second conductive layers may comprise a pattern of electrodes, and the pattern of electrodes may comprise a pattern of diamond-shaped electrodes. The first and second transparent substrates may comprise a plastic film. The capacitive touch screen panel may be at least partially manufactured using a roll-to-roll process. Once of the first and second conductive layers comprises an indium tin oxide (ITO) layer. The first and second sets of conductive traces may be formed of one or more of aluminum, copper, gold, and silver.

Also disclosed is a method of manufacturing a capacitive touch screen panel. The method includes depositing at least one conductive layer on a first side of a transparent substrate; removing selected portions of the at least one conductive layer; depositing at least one transparent conductive layer on the first side of the transparent substrate; and removing selected portions of the at least one transparent conductive layer, wherein the steps of removing retain an electrical connection between the at least one conductive layer and the at least one transparent conductive layer.

The depositing at least one conductive layer may comprise depositing at least one conductive layer via vacuum deposition, and the depositing at least one transparent conductive layer may comprise depositing at least one transparent conductive layer via vacuum deposition. The removing selective portions of the at least one conductive layer produces a plurality of conductive traces separated by spaces. A trace width of each of the conductive traces may be less than 80 μm, and a space width of each of the spaces may be less than 80 μm.

The method may further comprise patterning the at least one transparent layer, and the transparent conductive layer may comprise an ITO layer. The conductive layer may be formed of one or more of aluminum, copper, gold, and silver.

Also disclosed is a capacitive touch sensor. The capacitive touch sensor includes a transparent substrate having a transparent conductive layer disposed adjacent to a surface thereof and a set of conductive traces disposed on the first transparent substrate, wherein the conductive traces are in conductive communication with the transparent conductive layer, and wherein the conductive traces are deposited using electro deposition or vacuum deposition.

The transparent conductive layer may be patterned, and the conductive traces may electrically connect with a bottom surface of the transparent conductive layer.

### BRIEF DESCRIPTION OF THE DRAWINGS

FIGS. 1A and 1B illustrate a top view and cross-sectional view of a prior art capacitive touch screen sensor assembly.

FIG. 2 illustrates a functional schematic of an automatic teller machine that incorporates an exemplary touch screen sensor assembly.

FIG. 3 illustrates an automatic teller machine that incorporates an exemplary touch screen sensor assembly.

FIG. 4 illustrates a schematic of one configuration of various layers for an exemplary touch screen sensor assembly.

FIG. 5 illustrates a top layer of transparent conductive material for an exemplary touch screen sensor assembly.

FIG. 6 is a flow chart depicting an exemplary method of manufacturing a touch screen sensor assembly.

FIGS. 7A and 7B show two embodiments of the interface between a transparent conductive layer and a metal layer.

FIG. 8 illustrates a schematic of another configuration of various layers for an exemplary touch screen sensor assembly.

### DETAILED DESCRIPTION

While the invention is susceptible to various modifications and alternative forms, specific embodiments thereof have been shown by way of example in the drawings and are herein described in detail. It should be understood, however, that it is not intended to limit the invention to the particular form disclosed, but rather, the invention is to cover all modifications, equivalents, and alternatives falling within the scope and spirit of the invention as defined by the claims.

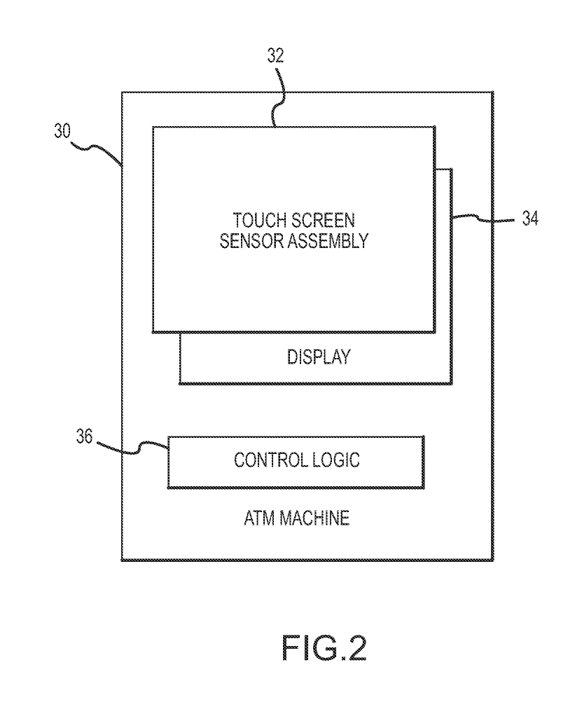

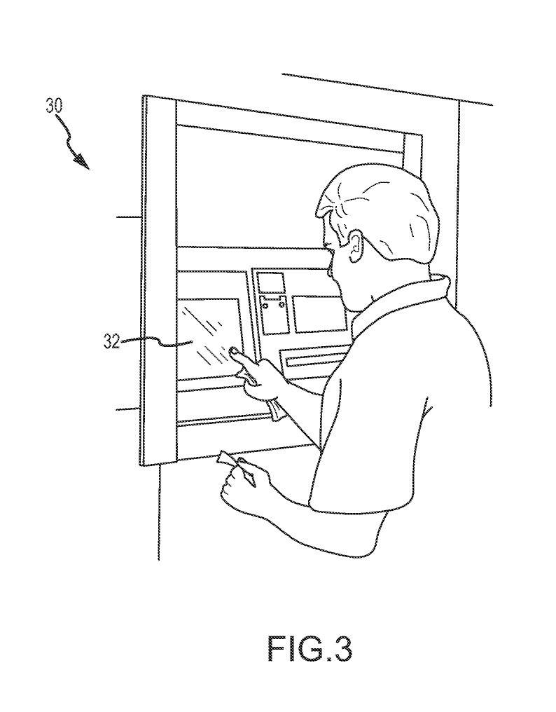

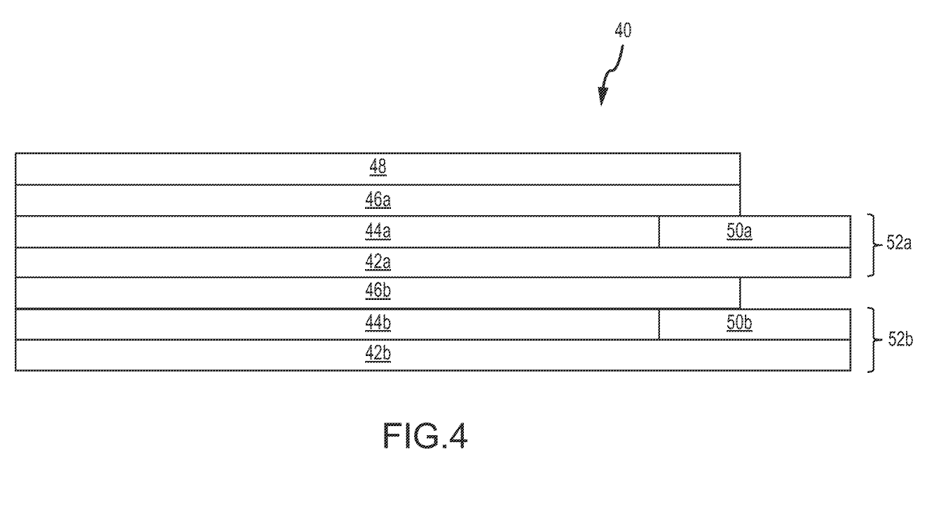

FIGS. 2 and 3 illustrate an automatic teller machine (ATM) 30 that incorporates an exemplary touch screen sensor assembly 32. Although the ATM 30 is illustrated, the embodiments described herein may be incorporated into any electronic device that incorporates a touch screen or pad, such as a personal digital assistant (PDA), a casino game machine, a mobile phone, a computer, a voting machine, a laptop mouse pad, or any other electronic device. In this embodiment, the touch screen sensor assembly 32 may include two layers of transparent patterned conductive material, such as ITO, that are disposed on two substrates positioned in a spaced, parallel relationship (FIG. 4). The touch screen sensor assembly 32 may also be coupled to control logic 36 (FIG. 2) that is operable to excite the conductive material and to sense touches on or near the touch screen sensor assembly 32. As an example, the control logic 36 may include a commercial touch screen controller (e.g., a controller provided by Cypress Semiconductor, Analog Devices, Atmel, Synaptics, and others), an application specific integrated circuit (ASIC), or any other suitable controller. Further, the touch sensor assembly 32 may overlay a display 34 (FIG. 2), which may be any type of display, such as a liquid crystal display (LCD).

FIG. 4 illustrates several layers that may be included in an exemplary touch screen sensor assembly 40. The assembly 40 may include a top substrate 42a that may be any suitable transparent material, including glass or polymer, such as polyethylene terephthalate (PET). A metal may be deposited onto the top substrate 42a, for example through vacuum deposition, sputtering, chemical vapor deposition, electro deposition, or any other suitable deposition technique. The metal, once deposited, may be patterned into a desired shape using a mask and etch process to form conductive traces 50a. The conductive traces 50a deposited onto the substrate may be, but are not limited to, aluminum, copper, gold, silver, or a combination thereof. In addition, a passivation layer may also be deposited (not shown).

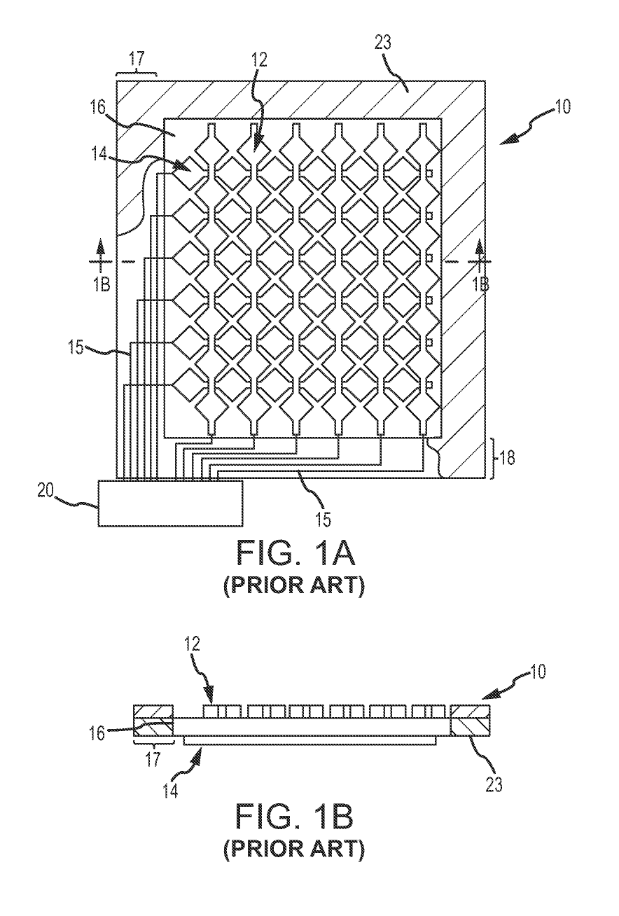

Furthermore, the top substrate 42a may also have a transparent conductive layer of ITO 44a deposited onto it through vacuum deposition, chemical vapor deposition, sputtering, electro deposition, or any other suitable deposition technique. The top ITO layer 44a may also undergo a mask and etch process wherein the top ITO layer 44a is patterned into a desired shape. The shape, for example, may be a diamond-type pattern as shown in FIG. 1A.

The touch sensor assembly 40 also includes a bottom substrate 42b. The bottom substrate 42b may be any suitable transparent material, including glass or polymer, such as PET. A metal may be deposited onto the bottom substrate 42b, for example through vacuum deposition, sputtering, chemical vapor deposition, electro deposition, or another suitable deposition technique. The metal, once deposited, may further be patterned into a desired shape using a mask and etch process to from conductive traces 50b. The conductive traces 50b deposited onto the substrate may be, but are not limited to, aluminum, copper, gold, silver, or a combination thereof. In addition, a passivation layer may also be deposited (not shown).

Furthermore, the bottom substrate 42b may also have a transparent conductive layer of ITO 44b deposited onto it through vacuum deposition, chemical vapor deposition, sputtering, electro deposition, or another suitable deposition technique. The bottom ITO layer 44b may also undergo a mask and etch process wherein the bottom ITO layer 44b is patterned into a desired shape. The shape may be, for example, a diamond-type pattern as shown in FIG. 1A.

The top substrate 42a, top ITO layer 44a, and conductive traces 50a may form a top layer 52a. Similarly, the bottom substrate 42b, bottom ITO layer 44b, and conductive traces 50b may form a bottom layer 52b. The top layer 52a and bottom layer 52b may be adhered together by a layer of optically clear adhesive (OCA) 46b. The OCA layer 46b may be a pressure sensitive adhesive. By way of example, the OCA layer 46b may be a pressure sensitive OCA sold by 3M Electronics.

In addition, the top layer 52a may have a cover layer 48 adhered to it such that the top ITO layer 44a has an OCA layer 46a placed adjacent to it. A cover layer 48 may be applied to the OCA 46a such that the cover layer 48 is adhered to the top layer 52a. The cover layer 48 may include any suitable transparent medium. By way of example, the cover layer 48 may be glass or polymer, such as PET.

The top ITO layer 44a and the conductive traces 50a may be deposited onto the top substrate 42a in such a way that the conductive top ITO layer 44a is in conductive contact with the conductive traces 50a. In this regard, electric signals supplied to or received from the top ITO layer 44a may be transmitted via the conductive traces 50a to or from control logic 36 (as shown in FIG. 2). In this regard, the conductive traces 50a establish a conductive path with the top ITO layer 44a.

Also, the bottom ITO layer 44b and the conductive traces 50b may be deposited onto the bottom substrate 42b in such a way that the conductive bottom ITO layer 44b is in conductive contact with the conductive traces 50b. In this regard, electric signals supplied to or received from the bottom ITO layer 44b may be transmitted via the conductive traces 50b to or from control logic 36 (as shown in FIG. 2). In this regard, the conductive traces 50b establish a conductive path with the bottom ITO layer 44b.

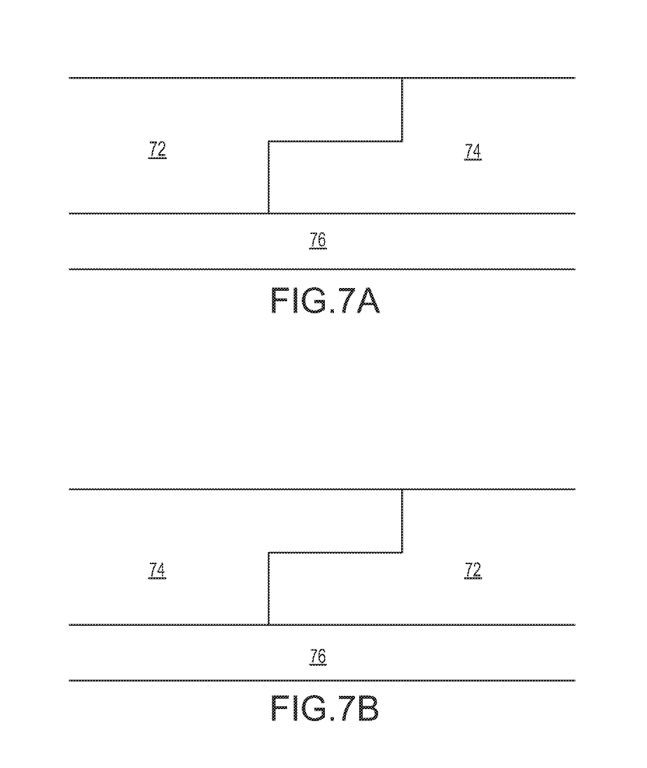

In another embodiment, shown in FIG. 7A, a metallic layer 74 may be overlapped by a transparent conductive layer 72 to establish a conductive connection between the two. The metallic layer 74 and the transparent conducive layer 72 may be formed on a transparent substrate 76. In an alternative embodiment shown in FIG. 7B, the metallic layer 74 may overlap the conductive layer 72 such that the conductive communication is established. Again, the metallic layer 74 and the transparent conducive layer 72 may be formed on a transparent substrate 76. The interface between the metallic layer 74 and the transparent conductive layer 72 may be of either configuration, or the layers may overlap each other in any alternative configuration that achieves a conductive configuration.

In so much as the conductive traces 50a and 50b may be deposited and patterned according to deposition, mask, etch, and strip techniques, the shape of the conductive traces 50a and 50b may be closely controlled. In this regard, each of the conductive traces may have a trace width that is less than 200 μm. Further still, each of the conductive traces may have a trace width that is less than 100 μm, and in one embodiment, less than 80 μm. As such, the conductive traces 50a and 50b may be arranged such that the traces may be formed in an area smaller than the area required to accommodate the same number of traces applied via a screen printing process. This allows for the conductive connection between the top and bottom ITO layers 44a and 44b to occupy a relatively small area. As the conductive connections have traditionally occupied significant space, the borders of touch sensitive panels have been relatively large. An embodiment of the present invention may have trace widths that are less than 80 μm so that the traces 50a, 50b of the present embodiment may be contained in a much smaller envelope. This may reduce the requisite border size of the touch sensitive panel.

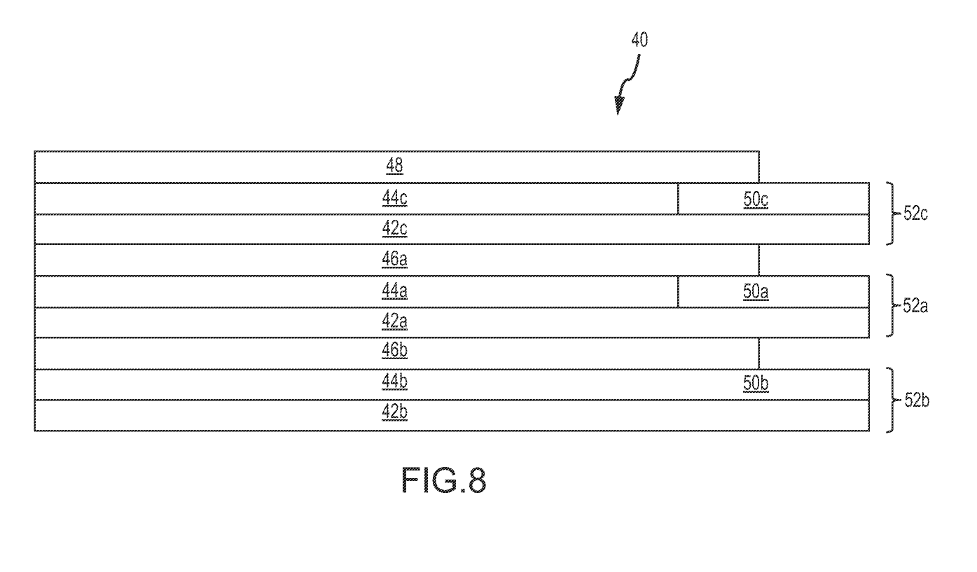

In another embodiment shown in FIG. 8, the touch screen sensor 40 may also include a third layer 52c. In FIG. 8, the third layer 52c is positioned between the OCA 46a and the cover layer 48. The third layer 52c may include a third substrate 42c. The third substrate 42c may be any suitable transparent material such as, for example, glass or polymer (e.g., PET). A metal may be deposited onto the third substrate 42c in any appropriate manner, including vacuum deposition, electro deposition, sputtering, chemical vapor deposition, or in one embodiment, a traditional screen printing process. The metal may be any appropriate metal such as, for instance, one or more of aluminum, copper, gold, and silver. Once deposited, the metal may be patterned into conductive traces 50c using a mask and etch process, as discussed above.

In one embodiment, a transparent conductive layer 44c (e.g., an ITO layer) may also be deposited onto the third substrate 42c using any appropriate process. The transparent conductive layer may optionally undergo a mask and etch process to pattern the transparent conductive layer 44c into any desired shape such as the diamond-type pattern discussed above and shown in FIG. 1A. Alternatively, the transparent conductive layer 44c may function as a cohesive conductive layer in a non-patterned arrangement.

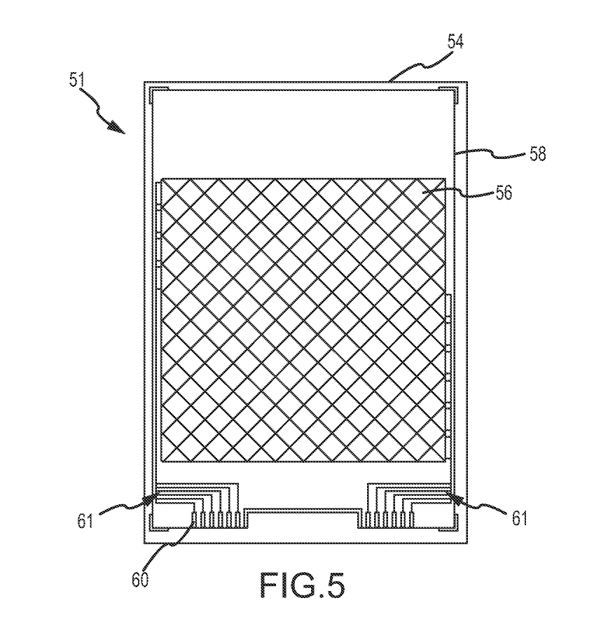

FIG. 5 details one embodiment of a top layer 51. The top layer 51 may have a transparent substrate 54. The transparent substrate 54 may be any suitable transparent material such as glass or polymer. In one embodiment the transparent substrate 54 is PET. The top layer 51 also may have deposited thereon a transparent conductive layer 56. The transparent conductive layer may be ITO in one embodiment. Furthermore, the transparent conductive layer 56 may be patterned such that it is in the shape of interconnected diamonds or another shape. The top layer 51 may include conductive traces 61. The conductive traces 61 may be any appropriate metal, such as aluminum, gold, silver, copper, or a combination thereof. The conductive traces 61 may contact the transparent conductive layer 56 such that the transparent conductive layer 56 and the conductive traces 61 may be in conductive communication. The conductive traces 61 may terminate in a contact 60. The contact 60 may then, in turn, communicate with a controller or other host device. Additionally, the top layer may be separated from the bulk of the transparent substrate 54 along a cut line 58.

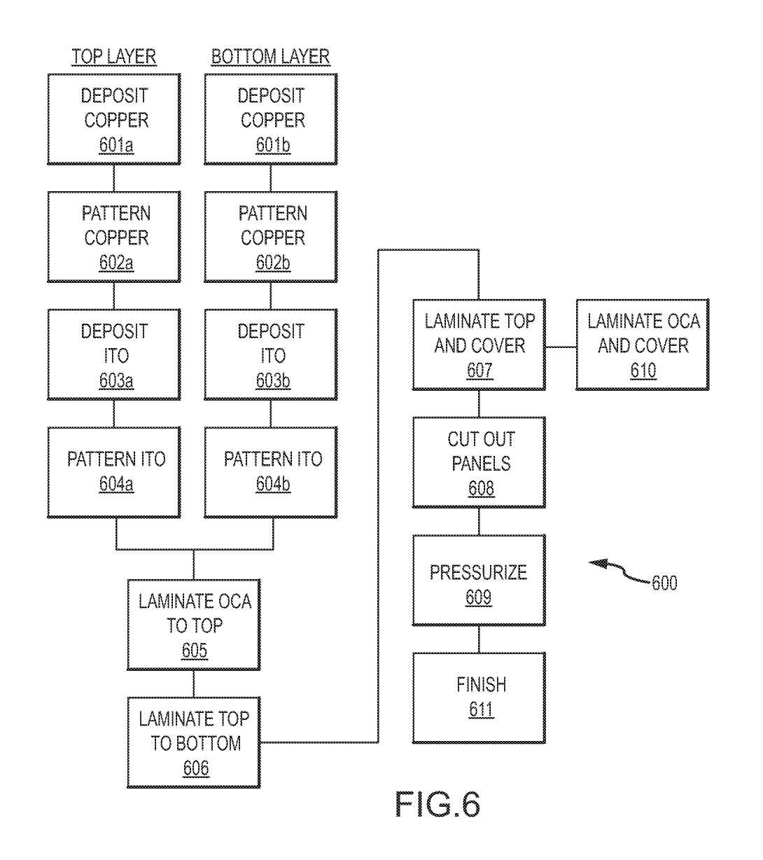

FIG. 6 is a flow chart depicting one embodiment of a method 600 of producing a touch screen panel. To produce the top and bottom layers 52a, 52b, discussed above, the process may initiate (601a, 601b) when metal is deposited onto a substrate using, for example, electro deposition or vacuum deposition. The metal may be, but is not limited to aluminum, copper, gold, silver, or a combination thereof. In one embodiment, the metal is copper. The substrate may be any suitable transparent material. In one embodiment, the substrate is PET. The deposited copper may undergo a process (602a, 602b) to pattern the copper into desired shapes. This may include application of a photoresist material to the deposited copper. The photoresist material may be in the form of photoresist film applied to the deposited copper. The photoresist material may be developed according to a pattern. After developing the photo resist, an etch and strip process may be employed to remove copper from areas of the substrate resulting in patterned copper being left on the substrate. The pattern may be varied to produce different shapes of patterned copper on the substrate. For example, one pattern may be used for the top layer 52a and a different pattern be used for the bottom layer 52b to produce differently shaped copper traces on the top and bottom layers. The patterns may result in copper being deposited in a manner such that the trace widths of the deposited copper are finer than 80 μm.

Additionally, ITO may be deposited (603a, 603b) onto the substrate to form a layer of ITO. The layer of ITO may be patterned (604a, 604b) into a desired shape. This patterning (604a, 604b) may involve covering the ITO layer deposited (603a, 603b) in a photoresist material. The photoresist material may be in the form of a film applied to the deposited ITO layer. The photoresist material may then be developed according to a pattern. After developing the photo resist, an etch and strip process may be employed to remove ITO from areas of the substrate resulting in a patterned ITO layer deposited onto the substrate. The pattern may vary to produce different shapes of ITO on the substrate. For example, one pattern may be used for the top layer 52a and a different pattern be used for the bottom layer 52b to produce differently shaped ITO patterns on the bottom layer. The patterned ITO layers may be aligned and shaped such that the ITO layer is in conductive contact with the copper that has been patterned (602a, 602b).

It is to be understood that the process described herein may be used to produce both the top and bottom layers of the transparent assembly. The top and bottom layers may differ in that different patterns are used to pattern both the copper and the ITO. However, the top and bottom layer may be produced according to similar processes. This does not mean that the top and bottom layers are identical. In addition to different patterns, it is contemplated that the top and bottom layers may have different materials. For instance, the top layer substrate may be a polymer, while the bottom layer substrate may be glass. Additionally, similar materials may also be used.

An OCA may be laminated (605) to a top layer. The OCA may be an appropriate optically clear adhesive and in one embodiment is a pressure sensitive optically clear adhesive. A bottom layer may be laminated (606) to the top layer such that the OCA laminated to the top layer (605) is disposed between the top and bottom layer.

A cover layer may be laminated (610) with an OCA to prepare the cover layer for lamination. For instance, the cover layer may be laminated (607) to the top layer such that the OCA applied to the cover (610) is disposed between the top layer and the cover.

In the method 600, multiple assemblies may be produced such that the substrate may contain multiple individual assemblies on a single quantity of material. The panels produced, which may include a bottom layer laminated to a top layer that is in turn laminated to a cover, may be separated (608) from the remainder of the substrate such that the individual panels may be cut to an approximate final dimension. The separated assemblies may undergo a pressurization treatment (609). The pressurization treatment (609) may include, in one embodiment, placing the assemblies in an autoclave and subjecting the assemblies to a pressure greater than atmospheric pressure. The pressurization process may serve to activate the pressure sensitive adhesive. Moreover, this pressurization process may serve to remove any air bubbles that may develop during the lamination processes in previous steps. Such air bubbles are undesirable because they may cause visual blemishes in the resulting device.

Finally, the assemblies may be finished (611) and the assemblies may undergo inspection. The inspection may include ensuring that the assemblies are the appropriate size, that the assemblies are functional, that the proper conductivity is established, or that the assemblies are free of visual defects such as blemishes or air bubbles. In addition, the assemblies may be cut to final dimensions to ensure the finished assembly is within certain tolerances.

Additionally, while the method described and depicted in FIG. 6 includes deposition and patterning of metal onto the substrate prior to deposition and patterning of ITO onto the substrate, alternative embodiments are contemplated such that ITO is deposited and patterned prior to the deposition and patterning of metal. Further still, the method 600 may include multiple stages of deposition and patterning such that metal and ITO are deposited and patterned onto the substrate.

The method 600 of producing touch screen panels may be accomplished using various manufacturing techniques. In one embodiment, the method 600 is accomplished using a roll-to-roll technique. In this manner, the substrate upon which the processes are performed may be initially disposed on a continuous or semi continuous roll of material. The substrate may then be fed through machinery to accomplish the various processes of the method 600 and then spooled onto another roll once the process or processes are accomplished. This technique of roll-to-roll processing may be used in any one or more of the processes of method 600 without limitation. It is understood that a flexible substrate may be employed to effectuate the roll-to-roll processing. In addition, the method 600 may be accomplished using sheet processing such that multiple assemblies are produced from sheets of material. Further still, a combination of sheet and roll-to-roll processing may be used to accomplish the steps in method 600.

While the invention has been illustrated and described in detail in the drawings and foregoing description, such illustration and description is to be considered as exemplary and not restrictive in character. For example, certain embodiments described hereinabove may be combinable with other described embodiments and/or arranged in other ways (e.g., process elements may be performed in other sequences). Accordingly, it should be understood that only exemplary embodiments and variants thereof have been shown and described and that all changes and modifications that come within the spirit of the invention are desired to be protected.

1. A capacitive touch screen panel, comprising:
a first transparent substrate that includes a first conductive layer disposed adjacent to a surface thereof;
a second transparent substrate that includes a second conductive layer disposed adjacent to a surface thereof;
a first set of conductive traces disposed on the first transparent substrate and in conductive communication with the first conductive layer; and
a second set of conductive traces disposed on the second transparent substrate and in conductive communication with the second conductive layer, wherein at least one of the first set of conductive traces and the second set of conductive traces are deposited by one of electro deposition and vacuum deposition.

2. The capacitive touch screen panel of claim 1, wherein a space separates each of the conductive traces, and wherein each of the conductive traces has a trace width that is less than 80 μm, and wherein each of the spaces has a space width that is less than 80 μm.

3. The capacitive touch screen panel of claim 1, further comprising:
a third transparent substrate that includes a third conductive layer disposed adjacent to a surface thereof; and
a third set of conductive traces disposed on the third transparent substrate and in conductive communication with the third conductive layer, wherein the third set of conductive traces are deposited by electro deposition, vacuum deposition, or screen printing.

4. The capacitive touch screen panel of claim 1, wherein the first transparent substrate, the first conductive layer, and the first set of conductive traces form a top layer, and wherein a transparent cover layer is associated with the top layer.

5. The capacitive touch screen panel of claim 1, wherein the first set of conductive traces electrically connects with a top surface of the first conductive layer.

6. The capacitive touch screen panel of claim 1, wherein the first set of conductive traces electrically connects with a bottom surface of the first conductive layer.

7. The capacitive touch screen panel of claim 1, wherein one of the first and second conductive layers comprises a pattern of electrodes.

8. The capacitive touch screen panel of claim 7, wherein the pattern of electrodes comprises a pattern of diamond-shaped electrodes.

9. The capacitive touch screen panel of claim 1, wherein each of the first and second transparent substrates comprise a plastic film.

10. The capacitive touch screen panel of claim 1, wherein the capacitive touch screen panel is at least partially manufactured using a roll-to-roll process.

11. The capacitive touch screen panel of claim 1, wherein one of the first and second conductive layers comprises an indium tin oxide (ITO) layer.

12. The capacitive touch screen panel of claim 1, wherein the first and second sets of conductive traces are formed of one or more of aluminum, copper, gold, and silver.

13. A method of manufacturing a capacitive touch screen panel, the method comprising:
depositing at least one conductive layer on a first side of a transparent substrate;
removing selected portions of the at least one conductive layer;
depositing at least one transparent conductive layer on the first side of the transparent substrate; and
removing selected portions of the at least one transparent conductive layer, wherein the steps of removing retain an electrical connection between the at least one conductive layer and the at least one transparent conductive layer.

14. The method of claim 13, wherein the depositing at least one conductive layer comprises depositing at least one conductive layer via vacuum deposition.

15. The method of claim 14, wherein the depositing at least one transparent conductive layer comprises depositing at least one transparent conductive layer via vacuum deposition.

16. The method of claim 13, wherein the removing selective portions of the at least one conductive layer produces a plurality of conductive traces separated by spaces, and wherein a trace width of each of the conductive traces is less than 80 μm, and wherein a space width of each of the spaces is less than 80 μm

17. The method of claim 13, further comprising patterning the at least one transparent conductive layer.

18. The method of claim 13, wherein the transparent conductive layer comprises an indium tin oxide (ITO) layer.

19. The method of claim 13, wherein the conductive layer is formed of one or more of aluminum, copper, gold, and silver.

20. A capacitive touch sensor, comprising:
a transparent substrate having a transparent conductive layer disposed adjacent to a surface thereof; and
a set of conductive traces disposed on the first transparent substrate, wherein the conductive traces are in conductive communication with the transparent conductive layer, and wherein the conductive traces are deposited using electro deposition or vacuum deposition.

21. The capacitive touch sensor of claim 20, wherein the transparent conductive layer is patterned.

22. The capacitive touch sensor of claim 20, wherein conductive traces electrically connect with a bottom surface of the transparent conductive layer.
